(19) United States
(12) Patent Application Publication
(10) Pub. No.: US 2025/0080066 A1
(43) Pub. Date: Mar. 6, 2025

(54) Multipath Amplifier with Compact Power Splitting and Combining Transformers

(71) Applicant: Apple Inc., Cupertino, CA (US)

(72) Inventors: Fei Wang, Santa Clara, CA (US); Xiang Guan, Saratoga, CA (US)

(21) Appl. No.: 18/459,262

(22) Filed: Aug. 31, 2023

(51) Int. Cl. H03F 3/24; H03F 1/22

(52) U.S. Cl. CPC H03F 3/245; H03F 1/223; H03F 2200/451; H03F 2200/537

(57) ABSTRACT

Wireless circuitry is provided that includes at least a first amplifier, a second amplifier, and a power splitting transformer coupled to the first and second amplifiers. The first amplifier can include first input transistors, and the second amplifier can include second input transistors. The power splitting transformer can include a primary coil, a first secondary coil having terminals coupled to gate terminals of the first input transistors and having a center tap configured to receive a first bias voltage, and a second secondary coil having terminals coupled to gate terminals of the second input transistors and having a center tap configured to receive a second bias voltage. The first and second amplifiers may output signals to a power combining transformer. The power combining transformer can have a first primary coil, a second primary coil, and a secondary coil all disposed within a single compact transformer footprint.

### FIELD

This disclosure relates generally to electronic devices and, more particularly, to electronic devices with wireless communications circuitry.

### BACKGROUND

Electronic devices can be provided with wireless communications capabilities. An electronic device with wireless communications capabilities has wireless communications circuitry with one or more antennas. Wireless transceiver circuitry in the wireless communications circuitry uses the antennas to transmit and receive radio-frequency signals.

Radio-frequency signals transmitted by an antenna can be fed through a power amplifier, which is configured to amplify low power analog signals to higher power signals more suitable for transmission through the air over long distances. Radio-frequency signals received at an antenna can be fed through a low noise amplifier, which is configured to amplify low power analog signals to higher power signals for ease of processing at a receiver. It can be challenging to design satisfactory radio-frequency amplifier circuitry for an electronic device.

### SUMMARY

An electronic device may include wireless communications circuitry. The wireless communications circuitry may include one or more processors or signal processing blocks for generating baseband signals, a transceiver for upconverting (modulating) the baseband signals to radio frequencies and for downconverting (demodulating) radio-frequency signals to baseband signals, amplifiers configured to amplify radio-frequency signals prior to transmission at one or more antennas and to amplify signals received at one or more antennas in the electronic device.

An aspect of the disclosure provides a wireless circuitry that includes a first amplifier having first input transistors, a second amplifier having second input transistors, and a power splitting transformer. The power splitting transformer can include a primary coil, a first secondary coil having terminals coupled to gate terminals of the first input transistors and having a center tap configured to receive a first bias voltage that biases the gate terminals of the first input transistors, and a second secondary coil having terminals coupled to gate terminals of the second input transistors and having a center tap configured to receive a second bias voltage that biases the gate terminals of the second input transistors. The first amplifier has a first transconductance profile; the second amplifier can have a second transconductance profile different than the first transconductance profile; and the first bias voltage and the second bias voltage can have different voltage levels selected to minimize a third transconductance profile that is a sum of the first and second transconductance profiles. The first input transistors have a first gate capacitance; the second input transistors have a second gate capacitance; and the first bias voltage and the second bias voltage can have different voltage levels selected such that a variation in the first gate capacitance cancels out with a variation in the second gate capacitance.

An aspect of the disclosure provides wireless circuitry that includes a first amplifier having first input transistors, a second amplifier having second input transistors, and a power combining transformer. The power combining transformer can include a first primary coil coupled to the first input transistors of the first amplifier, a second primary coil coupled to the second input transistors of the second amplifier, and a secondary coil. The secondary coil can have a first terminal coupled to a first power supply line and a second terminal coupled to an output port of the power combining transformer. The first primary coil can have a center tap coupled to a second power supply line different than the first power supply line, and the second primary coil can have a center tap coupled to the second power supply line. The first primary coil has a first winding; the second primary coil has a second winding that can overlap directly with the first winding; the secondary coil can have an inner winding and an outer winding; and the first and second windings can be nested between the inner and outer windings.

An aspect of the disclosure provides circuitry that includes a power splitting impedance matching transformer, a power combining impedance matching transformer, a first amplifier coupled between the power splitting impedance matching transformer and the power combining impedance matching transformer, where the first amplifier is configured to receive a first bias voltage that provides the first amplifier with a first transconductance, and a second amplifier coupled between the power splitting impedance matching transformer and the power combining impedance matching transformer, where the second amplifier is configured to receive a second bias voltage that provides the second amplifier with a second transconductance different than the first transconductance. The power splitting impedance matching transformer can include a primary coil, a first secondary coil coupled to the first amplifier and having a center tap configured to receive the first bias voltage, and a second secondary coil coupled to the second amplifier and having a center tap configured to receive the second bias voltage. The power combining impedance matching transformer can include a first primary coil coupled to the first amplifier, a second primary coil coupled to the second amplifier, and a secondary coil having a first terminal coupled to a ground power supply line and having a second terminal coupled to an output port of the power combining impedance matching transformer.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having radio-frequency amplifiers in accordance with some embodiments.

FIG. 3 is a diagram of an illustrative multipath radio-frequency amplifier with a power splitting impedance matching transformer and a power combining impedance matching transformer in accordance with some embodiments.

FIG. 4 is a diagram shown an illustrative circuit implementation of the amplifier shown in FIG. 3 in accordance with some embodiments.

FIG. 5 is a plot of 3^{rd} order transconductance Gm3 as a function of gate bias voltage Vgs in accordance with some embodiments.

FIG. 6 is a plot of gate capacitance Cgs as a function of gate bias voltage Vgs in accordance with some embodiments.

FIG. 7A is a top (layout) plan view of an illustrative primary coil in a power splitting impedance matching transformer in accordance with some embodiments.

FIG. 7B is a top (layout) plan view of an illustrative first secondary coil in a power splitting impedance matching transformer in accordance with some embodiments.

FIG. 7C is a top (layout) plan view of an illustrative second secondary coil in a power splitting impedance matching transformer in accordance with some embodiments.

FIG. 7D is a top (layout) plan view of an illustrative power splitting impedance matching transformer that includes the various coils shown in FIGS. 7A, 7B, and 7C in accordance with some embodiments.

FIG. 7E is a cross-sectional side view of the power splitting impedance matching transformer shown in FIG. 7D in accordance with some embodiments.

FIG. 8A is a top (layout) plan view of an illustrative first primary coil in a power combining impedance matching transformer in accordance with some embodiments.

FIG. 8B is a top (layout) plan view of an illustrative second primary coil in a power combining impedance matching transformer in accordance with some embodiments.

FIG. 8C is a top (layout) plan view of an illustrative secondary coil in a power combining impedance matching transformer in accordance with some embodiments.

FIG. 8D is a top (layout) plan view of an illustrative power combining impedance matching transformer that includes the various coils shown in FIGS. 8A, 8B, and 8C in accordance with some embodiments.

FIG. 8E is a cross-sectional side view of the power combining impedance matching transformer shown in FIG. 8D in accordance with some embodiments.

### DETAILED DESCRIPTION

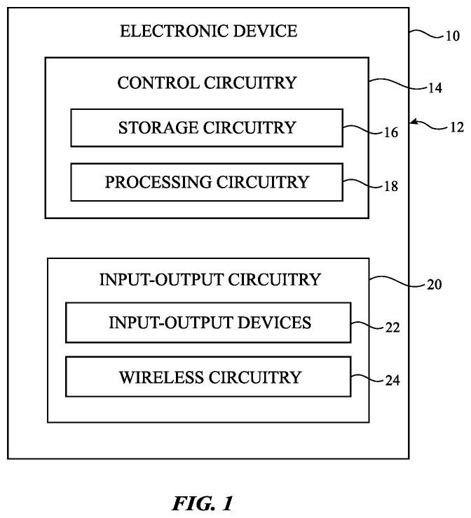

An electronic device such as device 10 of FIG. 1 may be provided with wireless circuitry. Wireless circuitry can include one or more radio-frequency transmitting amplifiers and radio-frequency receiving amplifiers. If care is not taken, non-linearity in the transistor devices of these radio-frequency amplifiers can introduce harmonic distortion, which can result in intermodulation components that cause undesired gain compression, signal interference, and other degradations in the overall performance of the wireless circuitry.

To address these problems, radio-frequency amplifier circuitry is provided that includes a power splitting transformer, a power combiner transformer, and at least two amplifiers (two amplifier paths) coupled in parallel between the power splitting transformer and the power combining transformer. The two amplifiers can be differential amplifiers with the same sized transistors that are biased differently to reduce the 3^{rd} order non-linearity components and thus reduce the amplitude modulation to amplitude modulation (AMAM) non-linearity, which reduces the input capacitance variation/sensitivity as a function of power and can also help reduce amplitude modulation to phase modulation (AMPM) non-linearity.

The power splitting transformer can include one primary coil and two secondary coils all disposed within a single compact transformer footprint, which reduces device parasitics while providing low-loss power splitting capability with balanced/symmetric impedance across all ports. The power combining transformer can include two primary coils and one secondary coil all disposed within a single compact transformer footprint, which reduces device parasitics while providing low-loss power combining capability with balanced/symmetric impedance across all ports. Configuring wireless circuitry in this way can be technically advantageous and beneficial by providing improved AMAM, AMPM, gain compression, in-band error vector magnitude (EVM), and out-of-band adjacent channel power ratio (ACPR) performance.

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, parts or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage. nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more microprocessors, microcontrollers, digital signal processors, host processors, baseband processor integrated circuits, application specific integrated circuits, central processing units (CPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols—sometimes referred to as Wi-Fi®), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 5G protocols, etc.), antenna diversity protocols, satellite navigation system protocols (e.g., global positioning system (GPS) protocols, global navigation satellite system (GLONASS) protocols, etc.), antenna-based spatial ranging protocols (e.g., radio detection and ranging (RADAR) protocols or other desired range detection protocols for signals conveyed at millimeter and centimeter wave frequencies), or any other desired communications protocols. Each communications protocol may be associated with a corresponding radio access technology (RAT) that specifies the physical connection methodology used in implementing the protocol.

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHZ WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHZ, 3G bands, 4G LTE bands, 5G New Radio Frequency Range 1(FR1) bands below 10 GHz, 5G New Radio Frequency Range 2 (FR2) bands between 20 and 60GHz, etc.), 6G bands between 100-1000 GHz (e.g., sub-THz, THz, tremendously high frequency or THF bands, etc.), other centimeter or millimeter wave frequency bands between 10-300 GHZ, near-field communications frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest.

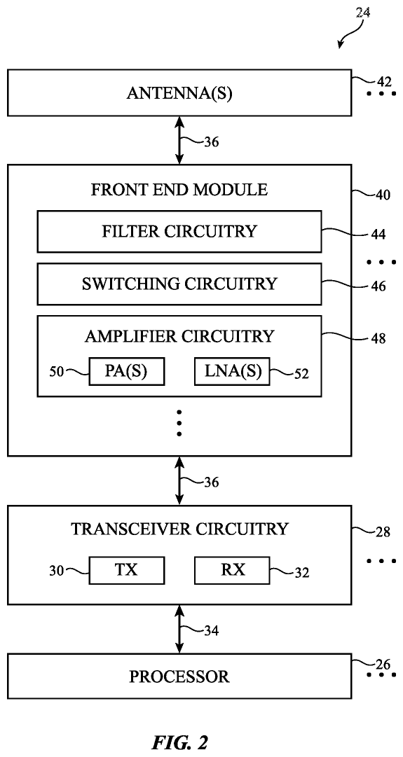

FIG. 2 is a diagram showing illustrative components within wireless circuitry 24. As shown in FIG. 2, wireless circuitry 24 may include a processor such as processor 26, radio-frequency (RF) transceiver circuitry such as radio-frequency transceiver 28, radio-frequency front end circuitry such as radio-frequency front end module (FEM) 40, and antenna(s) 42. Processor 26 may be a baseband processor, application processor, general purpose processor, microprocessor, microcontroller, digital signal processor, host processor, application specific signal processing hardware, or other type of processor. Processor 26 may be coupled to transceiver 28 over path 34. Transceiver 28 may be coupled to antenna 42 via radio-frequency transmission line path 36. Radio-frequency front end module 40 may be disposed on radio-frequency transmission line path 36 between transceiver 28 and antenna 42.

In the example of FIG. 2, wireless circuitry 24 is illustrated as including only a single processor 26, a single transceiver 28, a single front end module 40, and a single antenna 42 for the sake of clarity. In general, wireless circuitry 24 may include any desired number of processors 26, any desired number of transceivers 36, any desired number of front end modules 40, and any desired number of antennas 42. Each processor 26 may be coupled to one or more transceiver 28 over respective paths 34. Each transceiver 28 may include a transmitter circuit 30 configured to output uplink signals to antenna 42, may include a receiver circuit 32 configured to receive downlink signals from antenna 42, and may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path such that is coupled to the positive antenna feed terminal on antenna 42. Radio-frequency transmission line path 36 may have a ground transmission line signal path that is coupled to the ground antenna feed terminal on antenna 42. This example is merely illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

In performing wireless transmission, processor 26 may provide transmit signals (e.g., digital or baseband signals) to transceiver 28 over path 34. Transceiver 28 may further include circuitry for converting the transmit (baseband) signals received from processor 26 into corresponding radio-frequency signals. For example, transceiver circuitry 28 may include mixer circuitry for up-converting (or modulating) the transmit (baseband) signals to radio frequencies prior to transmission over antenna 42. The example of FIG. 2 in which processor 26 communicates with transceiver 28 is merely illustrative. In general, transceiver 28 may communicate with a baseband processor, an application processor, general purpose processor, a microcontroller, a microprocessor, or one or more processors within circuitry 18. Transceiver circuitry 28 may also include digital-to-analog converter (DAC) and/or analog-to-digital converter (ADC) circuitry for converting signals between digital and analog domains. Transceiver 28 may use transmitter (TX) 30 to transmit the radio-frequency signals over antenna 42 via radio-frequency transmission line path 36 and front end module 40. Antenna 42 may transmit the radio-frequency signals to external wireless equipment by radiating the radio-frequency signals into free space.

In performing wireless reception, antenna 42 may receive radio-frequency signals from the external wireless equipment. The received radio-frequency signals may be conveyed to transceiver 28 via radio-frequency transmission line path 36 and front end module 40. Transceiver 28 may include circuitry such as receiver (RX) 32 for receiving signals from front end module 40 and for converting the received radio-frequency signals into corresponding baseband signals. For example, transceiver 28 may include mixer circuitry for down-converting (or demodulating) the received radio-frequency signals to baseband frequencies prior to conveying the received signals to processor 26 over path 34.

Front end module (FEM) 40 may include radio-frequency front end circuitry that operates on the radio-frequency signals conveyed (transmitted and/or received) over radio-frequency transmission line path 36. FEM 40 may, for example, include front end module (FEM) components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifier circuits 50 and/or one or more low-noise amplifier circuits 52), impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in front end 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40. and/or may be incorporated into antenna 42 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antenna 42 over time.

Transceiver 28 may be separate from front end module 40. For example, transceiver 28 may be formed on another substrate such as the main logic board of device 10, a rigid printed circuit board, or flexible printed circuit that is not a part of front end module 40. While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processor 26 and/or portions of transceiver 28 (e.g., a host processor on transceiver 28) may form a part of control circuitry 14. Control circuitry 14 (e.g., portions of control circuitry 14 formed on processor 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband communications protocols, and/or any other desired radio-frequency transceiver circuitry for covering any other desired communications bands of interest.

Wireless circuitry 24 may include one or more antennas such as antenna 42. Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

It can be challenging to design a satisfactory radio-frequency amplifier for an electronic device. Radio-frequency amplifiers can include non-linear devices whose performance is oftentimes degraded due to intermodulation distortion. Intermodulation distortion arises when at least two signals at different frequencies are applied to a non-linear circuit and when the amplitude modulation or mixing (multiplication) of the two signals when their sum is raised to a power greater than one generates intermodulation products that are not just at harmonic frequencies (integer multiples) of either input signal but also at sums and differences of the input signal frequencies and also at sums and differences of multiples of those frequencies. Other undesirable effects of non-linear circuits an include harmonic distortion, gain compression, and desensitization, just to name a few. Third order transconductance, sometimes referred to and defined herein as “Gm3”, is a parameter that can be used to describe or quantify the nonlinearity of a device. Third order transconductance Gm3 is a measure of how the output current of a transistor varies in response to a change in the input voltage (e.g., Gm3 is a third order derivative of the output current with respect to the input voltage). Third order non-linearity or Gm3 can cause gain compression and third order intermodulation distortion, sometimes referred to as IM3 or IMD3.

Conventional amplifier designs can sometimes include a single amplifier path with input transistors that are biased using a single bias voltage. Non-linearity can degrade the performance of such single amplifier path designs. Other amplifier designs that employ multiple parallel amplifier paths for the purpose increasing the overall gain of the amplifier exacerbate the problem by further introducing even more non-linearity.

In accordance with an embodiment, wireless circuitry 24 can be provided with radio-frequency (RF) amplifier circuitry that is divided into multiple paths (see, e.g., FIG. 3). As shown in FIG. 3, the amplifier circuitry can be divided into at least a first amplifier (path) 64-1 and a second amplifier (path) 64-2. Compared to a conventional single-path amplifier design with a given target gain level, each of amplifiers 64-1 and 64-2 can be half the size of the single amplifier in the conventional design while achieving the same target gain level. Using multipath amplifiers 64-1 and 64-2 each with a reduced sizing can be technically advantageous and beneficial by maximizing gain and efficiency while improving the overall power performance. In some embodiments, amplifier 64-1 and amplifier 64-2 can be biased in different operating regions to reduce Gm3 or other non-linearity terms (e.g., to reduce second order non-linearity such as second order transconductance Gm2 or second order harmonic distortion HD2, third order harmonic distortion HD3, fourth order non-linearity such as fourth order transconductance Gm4 or fourth order harmonic distortion HD4, and/or other higher order non-linearity components).

The example of FIG. 3 in which the RF amplifier circuitry includes two parallel amplifier paths of reduced sizing is illustrative. In other embodiments, the RF amplifier circuitry can include three parallel amplifier paths each with ⅓ sizing, four parallel amplifier paths each with ¼ sizing. 4-10 parallel amplifier paths, or more than 10 parallel amplifier paths. Each amplifier path can have the same (identical) reduced sizing or can vary slightly in sizing. In embodiments where the sizing of the parallel amplifier paths are not identical, the various amplifier paths can deviate from one another in sizing by less than 5%, by less than 10%, by less than 20%, by less than 30%, or by other suitable amounts.

A power combining impedance matching network 66 can be coupled at the output ports of the parallel amplifiers (e.g., at the outputs of amplifiers 64-1 and 64-2) to combine the signals output from the parallel amplifiers. Power combining impedance matching network 66 can be implemented as a compact low-loss balanced (symmetrical) transformer that fits within a single transformer footprint and is thus sometimes referred to herein as a power combiner transformer. The power combiner transformer can also be configured to simultaneously provide an impedance matching function and can also thus be referred to as a power combining impedance matching transformer. A power splitting impedance matching network 62 can be coupled at the input ports of the parallel amplifiers (e.g., at the inputs of amplifiers 64-1 and 64-2) to split a single into multiple parallel paths. Power splitting impedance matching network 62 can be implemented as a compact low-loss balanced (symmetrical) transformer that fits within a single transformer footprint and is thus sometimes referred to herein as a power splitter transformer. The power splitter transformer can also be configured to simultaneously provide an impedance matching function and can also thus be referred to as a power splitting impedance matching transformer. Implementing power combiner and splitter networks as compact impedance matching transformers can help obviate the need for separate impedance matching networks at the input and/or output of the parallel amplifiers and can thus minimize circuit area and reduce cost.

Input driving circuits such as input driving circuits 60 can be coupled at the input of power splitter transformer 62. The input driving circuits 60 can optionally include one or more baluns, one or more input matching networks, one or more driver stages, and/or one or more interstage matching networks.

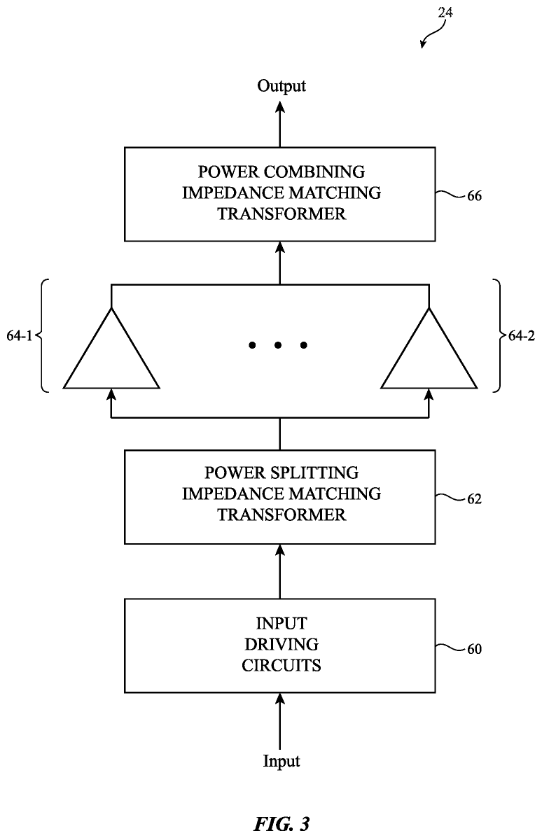

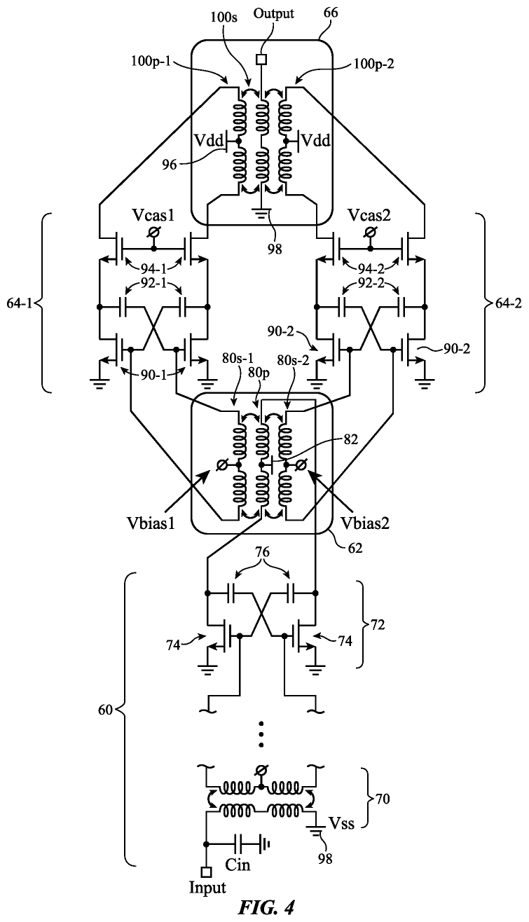

FIG. 4 is a diagram showing an illustrative circuit implementation of the amplifier circuitry shown in FIG. 3. As shown in FIG. 4, the first amplifier 64-1 may include input transistors 90-1, cross-coupled capacitors 92-1, and optional cascode transistors 94-1. The input transistors 90-1 may each have a gate terminal coupled to power splitting transformer 62, a source terminal coupled to a ground power supply line, and a drain terminal that is cross-coupled to the gate terminal of the other input transistor via one of the capacitors 92-1. The cascode transistors 94-1 may each have a source terminal coupled to a respective one of the input transistors 90-1, a gate terminal configured to receive a cascode bias voltage Vcas1, and a drain terminal coupled to power combining transformer 66. The terms “source” and “drain” are sometimes used interchangeably when referring to current-conducting terminals of a metal-oxide-semiconductor transistor. The source and drain terminals are therefore sometimes referred to as “source-drain” terminals (e.g., a transistor has a gate terminal, a first source-drain terminal, and a second source-drain terminal).

The second amplifier 64-2 may have a similar structure as the first amplifier 64-1. The second amplifier 64-2 may include its own input transistors 90-2, cross-coupled capacitors 92-2. and optional cascode transistors 94-2. The input transistors 90-2 may each have a gate terminal coupled to power splitting transformer 62, a source terminal coupled to the ground line, and a drain terminal that is cross-coupled to the gate terminal of the other input transistor via one of the capacitors 92-2. The cascode transistors 94-2 may each have a source terminal coupled to a respective one of the input transistors 90-2, a gate terminal configured to receive a cascode bias voltage Vcas2, and a drain terminal coupled to power combining transformer 66. Cascode bias voltages Vcas1 and Vcas2 can be different or can be equal. In the example of FIG. 4, the input transistors 90 and cascode transistors 94 in each amplifier 64-1 and 64-2 are implemented as n-type metal-oxide-semiconductor (NMOS) transistors. This is exemplary. If desired, at least some of the transistors within the multiple amplifier paths can alternatively be implemented as p-type metal-oxide-semiconductor (PMOS) transistors.

At the output side of the parallel amplifiers, power combining transformer 66 may include two primary coils (windings) such as first primary coil 100p-1 and second primary coil 100p-2 and only one secondary coil (winding) 100s. First primary coil 100p-1 may have a first terminal coupled to the drain terminal of a first input transistor 90-1 via an optional cascode transistor 94-1, a second terminal coupled to the drain terminal of a second input transistor 90-1 via an optional cascode transistor 94-1, and a center tap (terminal) coupled to a positive power supply line 96 (e.g., a positive power supply terminal on which positive power supply voltage Vdd is provided). Second primary coil 100p-2 may have a first terminal coupled to the drain terminal of a first input transistor 90-2 via an optional cascode transistor 94-2, a second terminal coupled to the drain terminal of a second input transistor 90-2 via an optional cascode transistor 94-2, and a center tap (terminal) coupled to positive power supply line 96. Secondary coil 100s may have a first terminal coupled to a ground power supply line 98 (sometimes referred to as a ground line or ground) and a second terminal configured as a single-ended output port of power combining transformer 66.

At the input side of the parallel amplifiers, power splitting transformer 62 may include only one primary coil (winding) such as primary coil 80p and two secondary coils (windings) 80s-1 and 80s-2. Primary coil 80p may have first and second opposing terminal coupled to the input driving circuits 60 and a center tap (terminal) coupled to voltage line 82. Voltage line 82 can be configured to receive positive power supply Vdd, ground power supply Vss, some intermediate voltage between Vdd and Vss, or other bias voltage. First secondary coil 80s-1 may have a first terminal coupled to the gate terminal of the first input transistor 90-1, a second terminal coupled to the gate terminal of the second input transistor 90-1, and a center tap (terminal) configured to receive a first bias voltage Vbias1. Second secondary coil 80s-2 may have a first terminal coupled to the gate terminal of the first input transistor 90-2, a second terminal coupled to the gate terminal of the second input transistor 90-2, and a center tap (terminal) configured to receive a second bias voltage Vbias2.

In accordance with some embodiments, the first bias voltage Vbias1 that is provided to the gate terminals of input transistors 90-1 in the first amplifier 64-1 can have a different voltage level than the second bias voltage Vbias2 that is provided to the gate terminals of input transistors 90-2 in the second amplifier 64-2, assuming input transistors 90-1 and 90-2 have the same transistor sizing. The voltage levels of Vbias1 and Vbias2 can be chosen to minimize the third order transconductance Gm3 or other non-linearity term(s) of the amplifier circuitry.

FIG. 5 is a plot of 3^{rd} order transconductance Gm3 as a function of gate bias voltage Vgs of the amplifier input transistors. Curve 110 may represent the Gm3 profile of a conventional single-path amplifier design having relatively large input transistors. Curve 112 may represent the Gm3 transconductance profile of the first amplifier path 64-1 with comparatively size-reduced input transistors. Curve 114 may represent the Gm3 transconductance profile of the second amplifier path 64-2 with comparatively sized-reduced input transistors. The Gm3 profiles 112 and 114 of the two parallel amplifier paths can be different. Curve 116 may represent the combined Gm3 transconductance profile of the two parallel amplifier paths (e.g., curve 116 is a sum of curves 112 and 114). As shown in FIG. 5, curve 116 of the combined Gm3 from the two parallel amplifier paths exhibits lower Gm3 peaks (positive and negative) compared to curve 110 of the conventional single-path amplifier design. This can help significantly reduce amplitude modulation to amplitude modulation (AMAM) non-linearity. Compared to curve 110, curve 116 also exhibits smaller slopes, which translates to less sensitivity or improved robustness to voltage variations. The bias voltages Vbias1 and Vbias2 can be selected to ensure that the combined Gm3 is relatively close to zero.

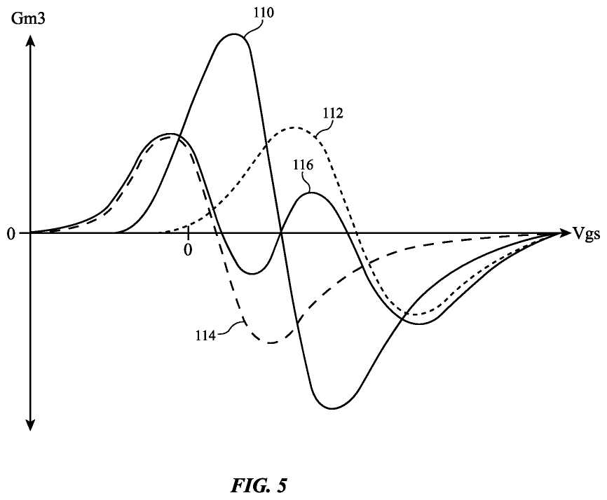

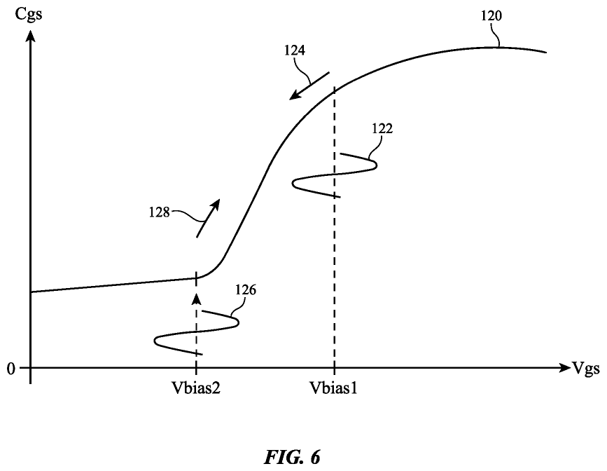

FIG. 6 is a plot of gate capacitance Cgs as a function of gate bias voltage Vgs of the amplifier input transistors. Curve 120 represents the gate capacitance profile, which increases as a function of gate bias voltage Vgs. As shown in FIG. 6, the bias voltage Vbias1 for the first amplifier path may be selected corresponding to a first (higher) region of curve 120 such that any small signal variation around the Vbias1 level (as shown by waveform 122) will translate to a general decrease in the gate capacitance Cgs, as indicated by arrow 124. Conversely, the bias voltage Vbias2 for the second amplifier path may be selected corresponding to a second (lower) region of curve 120 such that any small signal variation around the Vbias2 level (as shown by waveform 126) will translate to a general increase in the gate capacitance Cgs, as indicated by arrow 128. Biasing the two amplifier paths in this way can be technically advantageous and beneficial since the decrease in Cgs produced by the first amplifier path biased at Vbias1 can compensate or cancel out the increase in Cgs produced by the second amplifier path biased at Vbias2. Mitigating variation in the input capacitance of the multiple amplifier paths in this way can help significantly reduce amplitude modulation to phase modulation (AMPM) non-linearity.

The examples above generally refer to input transistors 90-1 in the first amplifier path and input transistors 90-2 in the second amplifier path having equal sizes. In some embodiments, the input transistors 90-1 in the first amplifier path can have different sizes than the input transistors 90-2 in the second amplifier path. In such embodiments, Vbias1 and Vbias2 can be the same voltage level or can have different voltage levels. In any scenario, bias voltage Vbias 1 for the first amplifier path and Vbias2 for the second amplifier path should be selected to minimize Gm3 (or other non-linearity term(s)) of the overall amplifier circuitry and/or to ensure that any variation in Cgs between the multiple amplifier paths can cancel out or offset one another.

Referring back to FIG. 4, input driver circuits 60 can include one or more input matching network 70, one or more driver stage 72, one or more interstage matching network, and/or other signal driving components. As shown in FIG. 4, input matching network 70 can include an input shunt capacitor Cin and an input balun. Driver stage 72 can include a pair of driving transistors 74 (e.g., NMOS driver transistors) connected to cross-coupled capacitors 76. These examples are merely illustrative. Other types of input matching networks 70 can be employed. Other types of differential driver stages can be employed. In general, input driver circuits 60 can include single-ended and/or differential impedance matching and signal driving circuits.

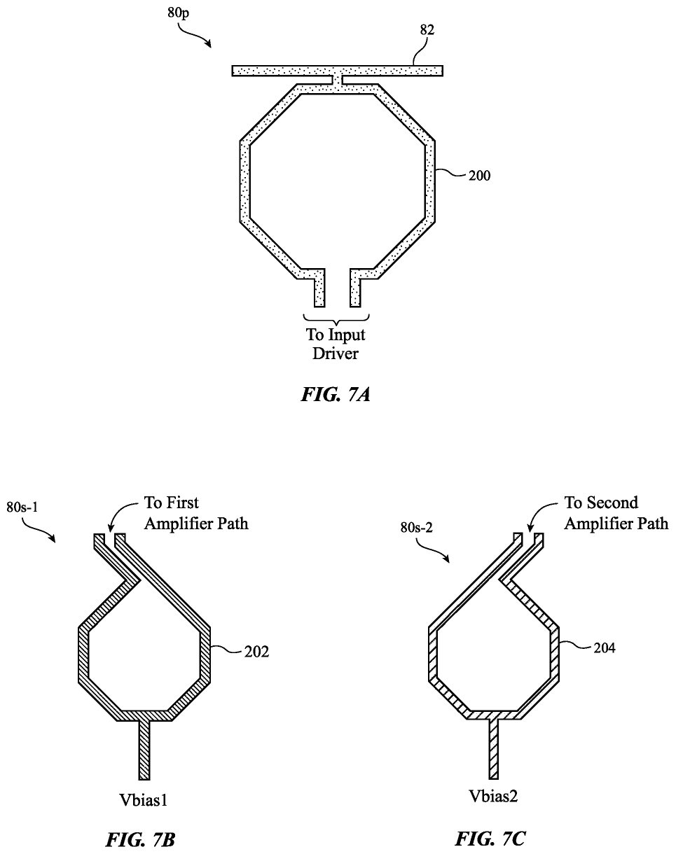

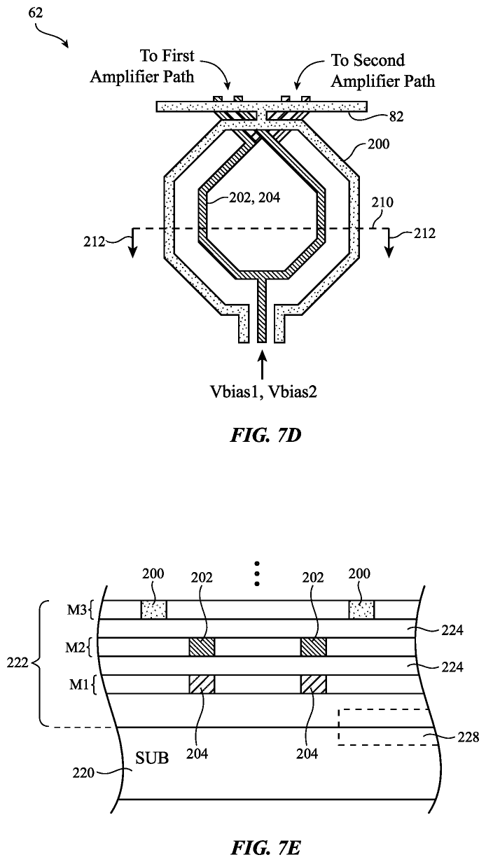

As described above, the bias voltages Vbias1 and Vbias2 of the two amplifier paths can be received at the power splitting transformer 62. The various coils of the power splitting transformer 62 are shown in FIGS. 7A-7E. FIG. 7A is a top (layout) plan view of primary coil 80p in power splitting transformer 62. As shown in FIG. 7A, primary coil 80p has a winding 200 with distal terminals coupled to the input driver circuits and a center tap coupled to bias voltage line 82. The example of FIG. 7A in which winding 200 has a single turn is merely illustrative. If desired, primary coil 80p can have multiple turns.

FIG. 7B is a top (layout) plan view of the first secondary coil 80s-1 in power splitting transformer 62. As shown in FIG. 7B, secondary coil 80s-1 has a winding 202 with distal terminals coupled to the first amplifier path and a center tap coupled to the first bias voltage Vbias1 (e.g., a first bias voltage line). The example of FIG. 7B in which winding 202 has a single turn is merely illustrative. If desired, secondary coil 80s-1 can have multiple turns. In some embodiments, the footprint of secondary coil 80s-1 may be smaller than the footprint of primary coil 80p such that the peripheral border of winding 202 is nested within the inner border of winding 200 (see, e.g., FIG. 7D). In other embodiments, winding 202 can overlap directly with winding 200 such that coil 80p and coil 80s-1 have the same identical footprint, or winding 202 can have a larger footprint than winding 200 such that the peripheral border of winding 200 is nested within the inner border of winding 202. The footprint of a coil winding is sometimes referred to as a winding footprint or coil footprint.

FIG. 7C is a top (layout) plan view of the second secondary coil 80s-2 in power splitting transformer 62. As shown in FIG. 7C, secondary coil 80s-2 has a winding 204 with distal terminals coupled to the second amplifier path and a center tap coupled to the second bias voltage Vbias2 (e.g., a second bias voltage line). The example of FIG. 7C in which winding 204 has a single turn is merely illustrative. If desired, secondary coil 80s-2 can have multiple turns. The second secondary coil 80s-2 should have the same footprint and the same number of turns as the first secondary coil 80s-1.

FIG. 7D is a top (layout) plan view showing multiple coils within power splitting transformer 62. As shown in the example of FIG. 7D, the secondary coil windings 202 and 204 may have smaller footprints nested within the larger footprint of the primary coil winding 200. In other embodiments, windings 202/204 can overlap directly with winding 200 such that coil 80p and coil 80s-1 have the same identical footprint, or windings 202/204 can have a larger footprint than winding 200 such that the peripheral border of winding 200 is nested within the inner border of winding 202. Regardless, power splitting transformer 62 should have a compact single transformer footprint, which reduces device parasitics while providing low-loss power splitting capability with balanced/symmetric impedance across all ports.

FIG. 7E is a cross-sectional side view of power splitting transformer 62 cut along dotted line 210 and viewed in direction 212. As shown in FIG. 7E, an interconnect stack such as interconnect stack 222 can be formed on a semiconductor substrate 220. Semiconductor substrate 220 can be a p-type silicon substrate (as an example). Transistors can be formed at the front surface of substrate 220 (see, e.g., region 228). Interconnect stack 222 may include alternating routing layers and via layers 224. Each routing layer can include conductive (metal) routing paths formed in a layer of dielectric material. Each via layer 224 can include conductive (metal) vias formed in a layer of dielectric material. Interconnect stack 222 is therefore sometimes referred to as a dielectric stack (e.g., an interconnect stack having conductive routing paths formed within dielectric material such as silicon dioxide). The conductive routing structures and the conductive via structures can be formed using copper, aluminum, tungsten, titanium, gold, silver, nickel, a metal alloy, a combination of metals, and/or other types of conductive material.

As shown in FIG. 7E, winding 204 of secondary coil 80s-2 can be formed in a first metal routing layer M1; winding 202 of secondary coil 80s-1 can be formed in a second metal routing layer M2 above the M1 routing layer; and winding 200 of primary coil 80p can be formed in a third metal routing layer M3 above the M2 routing layer. Windings 202 and 204 may overlap directly on top of each other (e.g., winding 202 is not only disposed above winding 204 but covers winding 204 from above), whereas winding 200 has a larger or wider footprint than winding 202 or 204. The example of FIG. 7E in which winding 200 is formed in the M3 metal routing layer, winding 202 is formed in the M2 metal routing layer, and winding 204 is formed in the M1 metal routing layer is merely illustrative. In general, windings 200, 202, and 204 can be formed in other metal routing layers of dielectric stack 222 in any desired order (e.g., winding 202 can be formed above winding 200 or below winding 204, winding 204 can be formed above winding 200 or above winding 202, etc.).

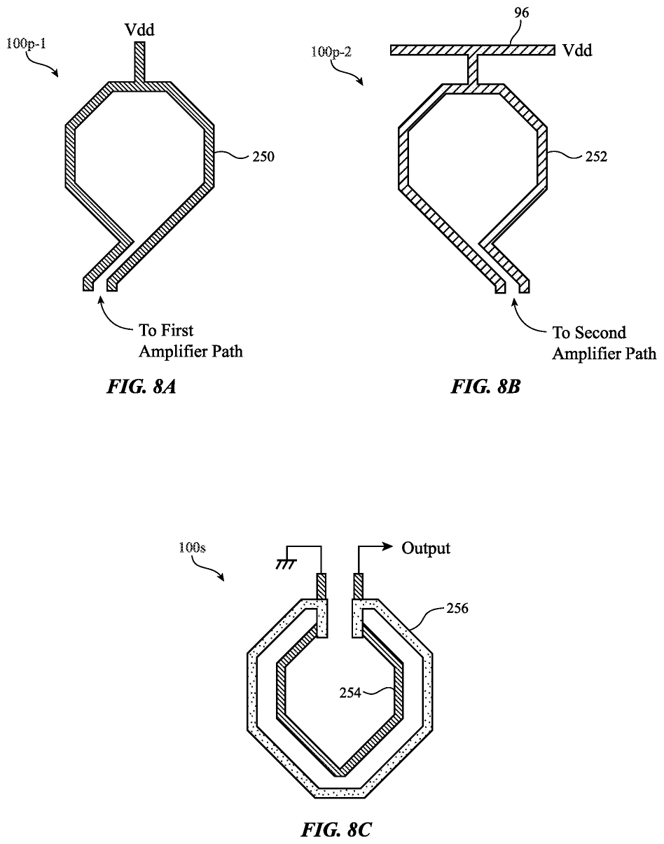

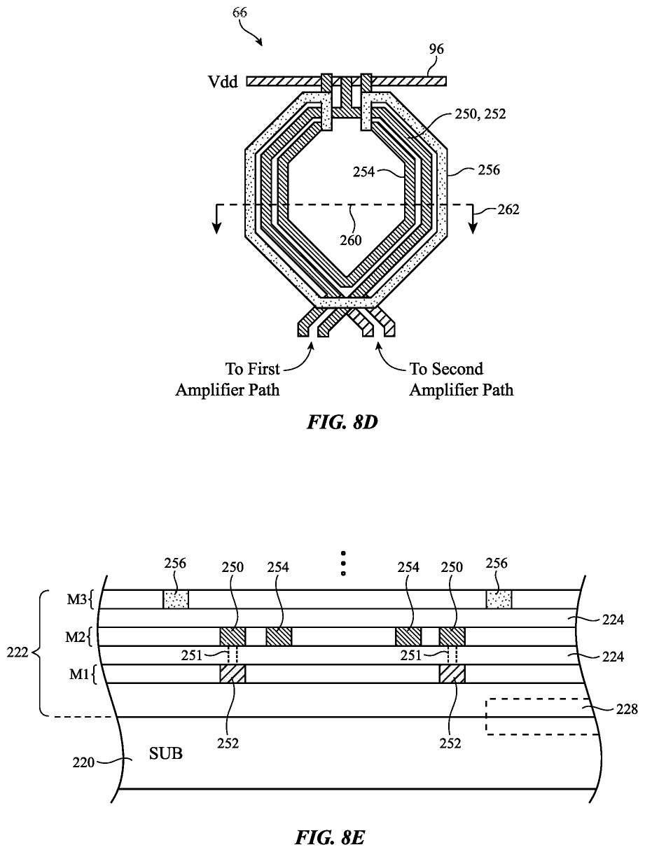

Turning now to the power combining transformer 66, the various coils within transformer 66 are shown in FIGS. 8A-8E. FIG. 8A is a top (layout) plan view of the first primary coil 100p-1 in power combining transformer 66. As shown in FIG. 8A, primary coil 100p-1 has a winding 250 with distal terminals coupled to the first amplifier path and a center tap coupled to the Vdd power supply line. The example of FIG. 8A in which winding 250 has a single turn is merely illustrative. If desired, primary coil 100p-1 can have multiple turns.

FIG. 8B is a top (layout) plan view of the second primary coil 100p-2 in power combining transformer 66. As shown in FIG. 8B, primary coil 100p-2 has a winding 252 with distal terminals coupled to the second amplifier path and a center tap coupled to the Vdd power supply line 96. The example of FIG. 8B in which winding 252 has a single turn is merely illustrative. If desired, primary coil 100p-2 can have multiple turns. The second primary coil 100p-2 should have the same footprint and the same number of turns as the first primary coil 100p-s1.

FIG. 8C is a top (layout) plan view of the secondary coil 100s in power combining transformer 66. As shown in FIG. 8C, secondary coil 100s has an inner winding 254 and an outer winding 256. Inner winding 254 and outer winding 256 can be formed in different metal routing layers of the dielectric stack. Inner winding 254 may have a first distal terminal coupled to the ground line and a second distal terminal coupled to the output port of the overall power combining transformer 66.

FIG. 8D is a top (layout) plan view showing multiple coils within power combining transformer 66. As shown in the example of FIG. 8D, the primary coil windings 250 and 252 can be nested within the inner windings 254 and the outer windings 256 of secondary coil 100s. This is exemplary. As another example, the primary coil windings 250/252 can lie directly above or under the outer winding 256. As another example, the primary coil windings 250/252 can lie directly above or under the inner winding 254. As another example, the primary coil windings 250/252 can have a larger footprint than the outer winding 256 (e.g., the windings of secondary coil 100s are nested within or surrounded by the primary coil windings, at least when observed from the plan view). As another example, the primary coil windings 250/252 can have a smaller footprint than the inner winding 254 (e.g., the primary coil windings are nested within or surrounded by the secondary coil winding, at least when observed from the plan view).

FIG. 8E is a cross-sectional side view of power combining transformer 66 cut along dotted line 260 and viewed in direction 262. As shown in FIG. 8E, an interconnect stack such as interconnect stack 222 can be formed on semiconductor substrate 220. Semiconductor substrate 220 can be a p-type silicon substrate (as an example). Transistors can be formed at the front surface of substrate 220 (sec, e.g., region 228). As shown in FIG. 8E, winding 252 of primary coil 100p-2 can be formed in the M1 routing layer; winding 250 of primary coil 100p-1 and winding 254 of secondary coil 100s can be formed in the M2 metal routing layer; and winding 256 of secondary coil 100s can be formed in the M3 routing layer M3. Windings 250 and 252 may overlap directly on top of each other (e.g., winding 250 is not only disposed above winding 252 but covers winding 252 from above). If desired, winding 250 and 252 can be shorted together in parallel or shunted together using optional via structures 251. The optional via structures 251 can be disposed along part of or along the entire circumference or peripheral border of windings 250/252. The example of FIG. 8E in which winding 256 is formed in the M3 metal routing layer, windings 250/254 are formed in the M2 metal routing layer, and winding 252 is formed in the M1 metal routing layer is merely illustrative. In general, windings 250, 252, 254, and 256 can be formed in other metal routing layers of dielectric stack 222 in any desired order (e.g., winding 256 can be formed below winding 250 or below winding 252, winding 252 can be formed above winding 256 or above winding 250, etc.).

The methods and operations described above in connection with FIGS. 1-8 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless communications circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 of FIG. 1, etc.). The processing circuitry may include microprocessors, application processors, digital signal processors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. Wireless circuitry comprising:
a first amplifier having first input transistors;
a second amplifier having second input transistors; and
a power splitting transformer that includes
a primary coil, and
a first secondary coil having terminals coupled to gate terminals of the first input transistors and having a center tap configured to receive a first bias voltage that biases the gate terminals of the first input transistors.

2. The wireless circuitry of claim 1, wherein the power splitting transformer further comprises:
a second secondary coil having terminals coupled to gate terminals of the second input transistors and having a center tap configured to receive a second bias voltage that biases the gate terminals of the second input transistors.

3. The wireless circuitry of claim 2, wherein the first amplifier has a first transconductance profile, wherein the second amplifier has a second transconductance profile different than the first transconductance profile, and wherein the first bias voltage and the second bias voltage have different voltage levels selected to minimize a third transconductance profile that is a sum of the first and second transconductance profiles.

4. The wireless circuitry of claim 2, wherein the first input transistors have a first gate capacitance, wherein the second input transistors have a second gate capacitance, and wherein the first bias voltage and the second bias voltage have different voltage levels selected such that a variation in the first gate capacitance cancels out with a variation in the second gate capacitance.

5. The wireless circuitry of claim 2, wherein the first amplifier further comprises first capacitors cross-coupled with the first input transistors, and wherein the second amplifier further comprises second capacitors cross-coupled with the second input transistors.

6. The wireless circuitry of claim 2, wherein the primary coil comprises terminals coupled to input driving circuits comprising one or more driver stages and one or more input matching networks.

7. The wireless circuitry of claim 2, wherein the primary coil has a first winding footprint, wherein the first secondary coil has a second winding footprint nested within the first winding footprint, wherein the second secondary coil has a third winding footprint identical to the second winding footprint, and wherein the second secondary coil overlaps directly with the first secondary coil.

8. The wireless circuitry of claim 2, wherein the primary coil is disposed in a first metal routing layer of an interconnect stack, wherein the first secondary coil is disposed in a second metal routing layer of the interconnect stack, and wherein the second secondary coil is disposed in a third metal routing layer, different than the first and second metal routing layers, of the interconnect stack.

9. The wireless circuitry of claim 1, further comprising:
a power combining transformer that includes
a first primary coil coupled to the first amplifier,
a second primary coil coupled to the second amplifier, and
a secondary coil having a first terminal coupled to a ground power supply line and having a second terminal coupled to an output port of the power combining transformer.

10. The wireless circuitry of claim 9, wherein the first primary coil has a first winding, wherein the second primary coil has a second winding that overlaps directly with the first winding, wherein the secondary coil has an inner winding and an outer winding, and wherein the first and second windings are nested between the inner and outer windings.

11. Wireless circuitry comprising:
a first amplifier having first input transistors;
a second amplifier having second input transistors; and
a power combining transformer that comprises
a first primary coil coupled to the first input transistors of the first amplifier,
a second primary coil coupled to the second input transistors of the second amplifier, and
a secondary coil.

12. The wireless circuitry of claim 11, wherein the secondary coil has a first terminal coupled to a first power supply line and has a second terminal coupled to an output port of the power combining transformer.

13. The wireless circuitry of claim 12, wherein the first primary coil has a center tap coupled to a second power supply line different than the first power supply line, and wherein the second primary coil has a center tap coupled to the second power supply line.

14. The wireless circuitry of claim 11, wherein the first primary coil has a first winding, wherein the second primary coil has a second winding that overlaps directly with the first winding, wherein the secondary coil has an inner winding and an outer winding, and wherein the first and second windings are nested between the inner and outer windings.

15. The wireless circuitry of claim 14, wherein the second winding is disposed in a first metal routing layer of an interconnect stack, wherein the first winding is disposed in a second metal routing layer of the interconnect stack, wherein the inner winding is disposed in the second metal routing layer, and wherein the outer winding is disposed in a third metal routing layer, different than the first and second metal routing layers, of the interconnect stack.

16. The wireless circuitry of claim 11, further comprising:
a power splitting transformer that includes
a primary coil,
a first secondary coil having terminals coupled to gate terminals of the first input transistors, and
a second secondary coil having terminals coupled to gate terminals of the second input transistors.

17. Circuitry comprising:
a power splitting impedance matching transformer;
a power combining impedance matching transformer;
a first amplifier coupled between the power splitting impedance matching transformer and the power combining impedance matching transformer, wherein the first amplifier is configured to receive a first bias voltage that provides the first amplifier with a first transconductance; and
a second amplifier coupled between the power splitting impedance matching transformer and the power combining impedance matching transformer, wherein the second amplifier is configured to receive a second bias voltage that provides the second amplifier with a second transconductance different than the first transconductance.

18. The circuitry of claim 17, wherein the power splitting impedance matching transformer comprises:
a primary coil;
a first secondary coil coupled to the first amplifier and having a center tap configured to receive the first bias voltage; and
a second secondary coil coupled to the second amplifier and having a center tap configured to receive the second bias voltage.

19. The circuitry of claim 17, wherein the power combining impedance matching transformer comprises:
a first primary coil coupled to the first amplifier;
a second primary coil coupled to the second amplifier; and
a secondary coil having a first terminal coupled to a ground power supply line and having a second terminal coupled to an output port of the power combining impedance matching transformer.

20. The circuitry of claim 19, wherein the first primary coil has a first winding, wherein the second primary coil has a second winding directly overlapping with the first winding, and wherein the first and second windings are coupled in parallel through a plurality of vias disposed along a circumference of the first winding.
